(19) United States
(12) Patent Application Publication
(10) Pub. No.: US 2010/0065110 A1
(43) Pub. Date: Mar. 18, 2010

(54) Method and Device for Converting Solar Power to Electrical Power

(76) Inventors: William A. Birdwell, Portland, OR (US); John Brockway Metcalf, Sherwood, OR (US)

Correspondence Address: Davis Wright Tremaine LLP - Portland;William A. Birdwell, 1300 S.W. Fifth Avenue, SUITE 2300, Portland, OR, 97201-5630, US

(21) Appl. No.: 12/557,506

(22) Filed: Sep. 10, 2009

Related U.S. Application Data
(60) Provisional application No. 61/095,911, filed on Sep. 10, 2008.

(51) Int. Cl. H01L 31/00

(52) U.S. Cl. 136/252

(57) ABSTRACT

A solar-to-electrical power conversion device. The conversion of broad energy band solar power to electrical power is accomplished by taking advantage of the fluorescence properties of materials that absorb solar power over a relatively broad range of energies and shift at least a portion of that power to emitted radiation over a relatively narrow range of energies at which the efficiency of a photovoltaic device is maximized. The absorbing material is fashioned to confine the emitted radiation so as to direct the emitted radiation to a photovoltaic device to convert that emitted radiation to electrical power. Preferably the absorbing material is the active medium of a solar-pumped laser, such as a fiber laser, that produces the emitted radiation. To absorb solar radiation while preventing unwanted emission of radiation at the nominal laser energy, the absorbing material is coated to be highly reflective at the nominal laser energy and highly transmissive over a relatively broad band of solar energy so as to absorb the broad band of solar energy yet couple emitted radiation to the photovoltaic device.

### CROSS REFERENCE TO RELATED APPLICATION

The present application claims the benefit of provisional U.S. Patent Application No. 61/095,911, filed Sep. 10, 2008, which is hereby incorporated by reference in its entirety.

### FIELD OF THE INVENTION

The present invention relates to methods and devices for converting solar power to electrical power, particularly methods and devices that first convert solar power from a relatively broad radiation energy spectrum to a relatively narrow radiation energy spectrum, then convert the narrow spectrum power to electrical power using photovoltaic methods and devices.

### SUMMARY OF THE INVENTION

The present invention provides a solar-to-electrical power conversion device. The conversion of broad energy band solar power to electrical power is accomplished by taking advantage of the fluorescence properties of materials that absorb solar power over a relatively broad range of energies and shift at least a portion of that power to emitted radiation over a relatively narrow range of energies. The absorbing material is fashioned to confine the emitted radiation so as to direct the emitted radiation to a device that will convert that emitted optical radiation to electrical power, such as a photovoltaic device.

Specifically, the device comprises a light amplifying medium having at least a ground electron state, an absorption band of electron states, and one intermediate electron state between the ground state and the absorption band of states, the capability of absorbing solar energy so as to produce an electron population inversion in the one intermediate state relative to a lower state, and the capability of allowing stimulated emission of light at a nominal laser energy by a transition from the one intermediate state to a lower state. It also comprises a first mirror that is at least partially reflecting at the nominal laser energy. It further comprises a second minor that is at least partially reflecting at the nominal laser energy, the laser medium being disposed between the first mirror and the second minor, the respective reflectivities of the first mirror and the second mirror being chosen so as to sustain laser oscillation while allowing light at the nominal laser energy to be emitted through at least the second minor. To produce electrical power, the device further comprises a photovoltaic device that is disposed so as to be illuminated by the light emitted through the second minor.

The laser medium is allowed to absorb solar radiation while preventing unwanted emission of radiation at the nominal laser energy, or wavelength. To that end, the device preferably also comprises a coating of material that, when applied to the laser medium, is highly reflective at the nominal laser energy and highly transmissive over a relatively broad band of solar energy, the coating being applied to the laser medium such that solar power over the broad band of solar energy is absorbed by the laser medium and converted to laser power at the nominal laser energy, thereby illuminating the photovoltaic device to produce electrical power.

It is to be understood that this summary is provided as a means of generally determining what follows in the drawings and detailed description, and is not intended to limit the scope of the invention. Objects, features and advantages of the invention will be readily understood upon consideration of the following detailed description taken in conjunction with the accompanying drawings.

### BRIEF DESCRIPTION OF THE DRAWINGS

FIG. 1 is a representation of a fiber optic solar-to-electrical power conversion device according to the principles of the present invention.

FIG. 2 is a representation of an embodiment of a fiber laser portion of a solar-to-electrical power conversion device according to the principles of the present invention.

FIG. 3 is an energy diagram for the fiber laser represented by FIG. 1.

FIG. 4 is a graph of power as a function of wavelength of optical radiation showing the relationship between solar power, solar power absorbed by the fiber laser of FIG. 1, laser radiation power produced by the fiber laser of FIG. 1, responsivity of a photovoltaic cell, and reflectivity of the lateral surface of the fiber coating of FIG. 1.

FIG. 5A is a representation of a first, preferred embodiment of a solar-to-electrical power conversion device according to the principles of the present invention.

FIG. 5B is a representation of the emission end of a fiber laser of a second embodiment of a solar-to-electrical power conversion device according to the present invention.

FIG. 5C is a representation of the emission end of a fiber laser of a third embodiment of a solar-to-electrical power conversion device according to the principles of the present invention.

FIG. 6A shows a fabric being woven from solar-to-electrical power conversion devices produced by a fiber laser of the type shown in FIG. 1 whose ends illuminate photovoltaic cells.

FIG. 6B shows the fabric of FIG. 5A disposed in a frame.

FIG. 7 is a representation of an end-pumped solar-to-electrical power conversion device according to the principles of the present invention.

FIG. 8 is a representation of a solar-to-electrical power conversion device according to the principles of the present invention in the form of a tile.

FIG. 9 is a representation of a solar-to-electrical power conversion device according to the principles of the present invention in the form of multiple stacked tiles.

### DETAILED DESCRIPTION OF EMBODIMENTS OF THE INVENTION

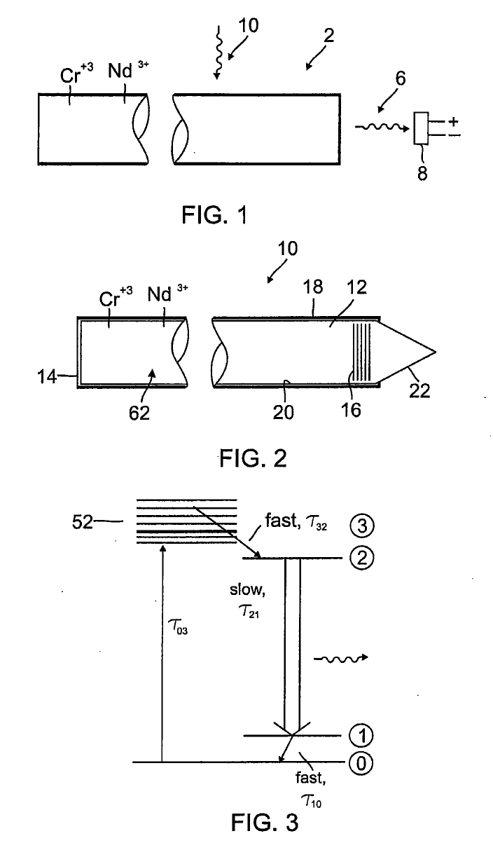

In the present invention the conversion of broad energy band solar power to electrical power is accomplished by taking advantage of the fluorescence properties of materials that absorb solar power over a relatively broad range of energies and shift at least a portion of that power to emitted radiation over a relatively narrow range of energies. The absorbing material is fashioned to confine the emitted radiation so as to direct the emitted radiation to a device that will convert that emitted optical radiation to electrical power, such as a photovoltaic device. This is illustrated, for example, by FIG. 1, wherein an optical fiber 2 made of glass is doped with, for example, neodymium (“Nd”) ions that fluoresce at specific energies by spontaneous decay from excited states and chromium (“Cr”) ions that will absorb radiation 4 over a broad band of energies and transfers much of that energy to excited states of the Nd ions by the interaction of phonons. The fiber guides the emitted light 6 to a photovoltaic device 8, such as a silicon p-n junction device, that produces an electric potential output. In the embodiments described below, features are provided that greatly improve the efficiency of such a solar power-to-electrical power conversion device and method.

In particular, according to the principles of the present invention, a laser medium absorbs solar power in the form of incoherent radiation over a broad energy spectrum and emits that power in the form of coherent radiation having a narrow energy spectrum. The emitted radiation is then absorbed by a photovoltaic device that converts it to electrical power. The photovoltaic device is chosen so as to have a radiation-to-electrical power conversion efficiency at the energy of radiation emitted by the laser medium that is relatively high in comparison to the efficiencies that can be achieved over the broad solar energy spectrum.

In a preferred embodiment, the laser medium is a component of a fiber laser 10, as shown in FIG. 2. The fiber laser comprises an optical fiber 12, having a first mirror 14, a second minor 16, spaced from mirror 14 so as to produce reflection of light through the fiber there between, and an optical coating 18 covering the lateral surface 20 of the fiber. Preferably, minor 14 is an essentially one hundred percent reflecting minor applied to the surface of a first, non-emitting end of the fiber laser and mirror 16 is a partially transmitting Bragg reflector disposed close to the second end of the fiber laser so as allow light produced by the laser to be emitted from the second end of the fiber, as is commonly understood in the art. Also preferably, the second end of the fiber is shaped so as to form a lens 22 that substantially collimates the light emitted by the fiber laser, as is also commonly understood in the art.

The optical fiber comprises material that absorbs solar radiation over a broad range of energies so as to produce an electron energy state population inversion therein, and produces radiation over a narrow range of energies as a result of stimulated emission. As is commonly understood in the art, to produce such a medium a host material, such as silicate or phosphate glass, is doped with impurities to produce a suitable energy level system. While a three-level energy system can be used to obtain the population inversion needed to create optical gain in the medium, in the present invention a four-level system, such as that illustrated by the energy-level diagram of FIG. 3, is preferred. In the four-level system of FIG. 3, electrons in the ground state “0” absorb energy from solar photons having a broad range of energies and are, consequently, raised to various states “3” in a “pump” energy band 52 in a pump transition Σ₀₃. Electrons in the various energy states of the pump band 52 then rapidly decay spontaneously to a first intermediate energy state “2” in a transition τ₃₂, from which their spontaneous decay is much slower so that an electron energy inversion builds up. Electrons in state “2” are then stimulated by photons having energy substantially equal to the difference in energy between state “2” and a lower state “1”, i.e., the nominal laser energy, to drop down to state “1” in a transition τ₂₁, thereby releasing another photon of the same characteristic energy. This is known as “stimulated emission” of radiation and is commonly understood in the art. Finally, electrons in state “1” rapidly decay spontaneously to the ground state “0”, so that a high population inversion between state “2” and state “1” is maintained. In the embodiment shown, the transitions τ₃₂ and τ₁₀ are non-radiative transitions, the energy released by those transitions being released as phonons.

While other systems may be used without departing from the principles of the invention, a system believed to be particularly suitable is a four-level system in which a silicate glass multimode fiber having a diameter of 200-500 μm is doped with neodymium and chromium ions. The neodymium provides the nominal laser transition τ₂₁, centered at about 1060 nm, and the chromium provides the energy band 50. A suitable combination of doping can be found from about 100 ppm to about 8000 ppm of Nd, and about 100 ppm to about 1000 ppm of Cr. An example of this can be found in T. Saiki, S. Uchida, K. Imaski, S. Motokoshi and M. Nakatsuka, “Solar-Pumped Nd dope Multimode-Fiber Laser with a D-Shaped Large Clad,” Proceedings, Beamed Energy Propulsion: Second International Symposium on Beamed Energy Propulsion (American Institute of Physics 0-7354-0175-6/04, hereinafter referred to as “T. Saiki et al.”), a copy of which accompanies this disclosure and is hereby incorporated by reference in its entirety.

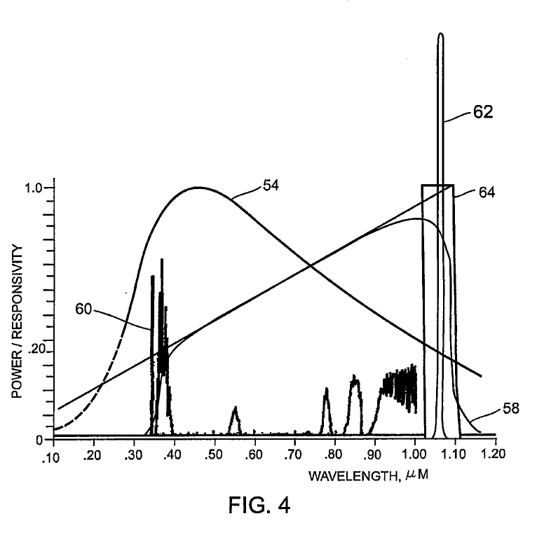

Turning now to FIG. 4, which plots power as a function of radiation energy, normalized to the power of solar radiation reaching the Earth and normalized to photodetector responsivity, the theoretical solar power (Blackbody radiation at 5800K) is shown by line 54, the ideal responsivity of a single junction silicon photovoltaic cell is shown by line 56, and the typical actual responsivity of such a photovoltaic cell is shown by line 58. (While responsivity is measured as current, it is directly proportional to the electrical power according to Ohm's law.) It can be seen that, while the peak solar radiation power is produced at a wavelength of about 500 nm (0.5 μm), the theoretical responsivity of the photovoltaic cell is highest at the bandgap energy E_{g} of the photovoltaic cell of 1.12 eV, or a wavelength of 1107 nm, and tapers down linearly as the energy increases (wavelength decreases) according to the equation:

SR=(qλ/hc)·QE

where

SR is the spectral responsivity (current),

QE is the quantum efficiency of the cell,

q is electric charge,

λ is wavelength,

h is Planck's constant, and

c is the speed of light.

Photons that have energy less than the bandgap energy, that is, have wavelengths (in air) longer than 1107 nm, are not absorbed. There is a mismatch between the spectral power distribution of solar energy and the ability of a single junction silicon cell to convert that solar power to electrical power. Instead, the energy of absorbed photons in excess of the bandgap energy is generally converted to heat rather than electrical power, as the electrons that absorb the energy of those photons drop down to lower states above the bandgap energy.

As shown by line 58, the actual responsivity of a single junction photovoltaic cell typically peaks at about 1050 nm and drops by about 50% at 500 nm; indeed, by 360 nm it is perhaps only about 5% of its maximum responsivity, yet solar radiation power is still relatively high. The laser medium is used to overcome this mismatch.¹ ¹The data regarding the actual responsivity of a typical photovoltaic cell comes from a web site published by pveducation.org.

When used as the laser medium in a fiber laser, the four-level silicate glass, neodymium and chromium system described above absorbs most of the solar radiation power and emits a large portion of that power as coherent radiation at 1060 nm. This is shown by line 60, which is the residual solar energy power after absorption by the fiber laser, where the glass was doped with 1000 ppm Nd and 1000 ppm Cr, and line 62, which is the emitted laser radiation power. FIG. 3(b) and FIG. 11 in T. Saiki et al., supra. That is, incoherent solar radiation power is absorbed over a broad energy spectrum and reradiated as coherent radiation having a wavelength near the maximum efficiency of a typical silicon solar cell. By illuminating such a photovoltaic cell with that radiation, high efficiency solar power-to-electrical power conversion can be achieved by the photovoltaic cell.

With the solar power-to-electrical power conversion efficiency of the photovoltaic cell maximized at a narrow energy band, the total system solar power-to-electrical power efficiency depends on the conversion efficiency of solar power to emitted laser radiation power in that band. For example, the paper by T. Saiki et al. identified above, reported that a conversion efficiency of 27% was achieved in the Cr/Nd doped silicate glass solar pumped fiber laser. For a photovoltaic cell having a maximum efficiency of 90% at the emitted laser radiation wavelength and a 90% coupling efficiency, the system solar power-to-electrical power conversion efficiency would be at 22%. Thus, not only does the present invention provide various convenient photovoltaic device form factors, but by the proper choice of dopants and host glass so as to increase the solar power-to-emitted laser radiation power conversion efficiency, a higher system solar power-to-electrical output power efficiency might be achieved.

An important aspect of the present invention is how to pump the laser medium with solar radiation efficiently, yet confine radiation at the nominal laser energy, or wavelength, of the stimulated radiation emission energy. Returning to FIG. 2, to achieve efficient pumping by solar power, the fiber laser is adapted to be pumped from the side. To that end, the outer surface 20 of the fiber 12 has an optical coating 20 disposed thereon that is antireflective over most of the solar spectrum, but highly reflective over a narrow band of wavelengths centered at the nominal laser wavelength and broad enough to include most of the power emitted by the laser, as shown by the reflectivity line 64 in the graph of FIG. 4. Consequently, the fiber can be pumped from the side, yet the stimulated radiation at the nominal laser wavelength is confined to the interior of the fiber, that is, the laser cavity. Preferably, to minimize reflection of solar power, the fiber does not include a cladding; however, a cladding may be included without departing from the principles of the invention.

A suitable optical coating may comprise a multilayer thin film coating that forms a minus filter, also known as a notch filter, which reflects a narrow wavelength band while transmitting the wavelength bands on both sides of the spectrum. The techniques for producing thin-film optical filters are well known in the thin film coating art and applications of those techniques to the production of notch filters can be found, for example, in Erdogen et al. U.S. Pat. No. 7,123,416; Pagis et al. U.S. Pat. No. 5,400,174; and U.S. Pat. No. 4,832,448, copies of all of which accompany this disclosure and are hereby incorporated by reference in their entireties. Where the solar-pumped fiber lasers described herein are arranged so that their outer surfaces contact one another, as in the spiral and woven embodiments described below, the last layer of the multi-layer thin film coating should preferably have an index of refraction as close to one as possible so as to prevent altering the characteristics of the thin-film stack at the points of contact.

It is to be recognized that other means of allowing the laser medium is to absorb solar radiation while preventing unwanted emission of radiation at the narrow wavelength band of the laser may be employed without departing from the principles of the invention.

In the preferred embodiment, a laser cavity 62 of fiber laser 10 is formed by the first mirror 14 and the second mirror 16. Ordinarily, the object is for light only to exit at one end of the fiber, so the first mirror is made to be essentially 100% reflective. This can be done in various ways, including placing a metal reflective material or a multi-layer thin film on one end of the fiber to form mirror 14. However, to avoid an external minor, mirror 16 is formed in the fiber as a Bragg grating, the spacing between mirror 14 and mirror 16 being equal to an integral number of half wavelengths at the nominal laser wavelength in the medium, as is well understood in the art.

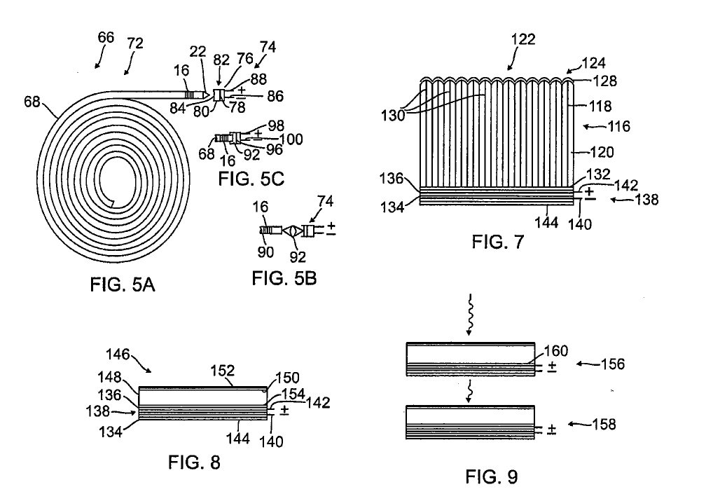

Turning now to FIG. 5A, in a first embodiment of a solar-to-electrical power conversion device 66 a solar-pumped fiber laser 68 with a lensed end as shown in FIG. 2 is wound in a spiral, the end with 100% reflectivity mirror 14 being at the center 70 of the spiral and the partially reflective minor 16 being near the other end of the fiber at the outside 72 of the spiral. The output light from the fiber laser is focused on a photovoltaic device 74. The photovoltaic device may be, for example, a single-junction silicon device having the characteristics described above and comprising a package 76, a n-doped layer 78 and an p-doped layer 80 forming a p-n junction 82, an antireflection coating 84 whose minimum reflection is selected to be at the characteristic wavelength of the laser, a first electrode 86 connected to the n-doped layer and a second electrode 88 connected to the p-doped layer.

Alternatively, as shown in FIG. 5B, a fiber laser 92 without a lensed end could terminate at the output end without a lens being formed thereon and be coupled to the photovoltaic device by a separate lens 94.

As another alternative, the fiber laser could be directly coupled to a photovoltaic device by forming the device on the end of the laser, as shown in FIG. 5C. Thus, a layer of n-doped silicon 94 is applied to the end of the fiber, followed by a layer of n-doped silicon 96, thereby forming a p-n junction. A first electrode 98 is connected to the p-doped layer and a second electrode 100 is connected to the n-doped layer, the assembly being protected by packaging 102.

It is to be understood that, while this and the remaining embodiments are explained assuming that the photovoltaic device is a single-junction silicon device, other types of photovoltaic devices could be used without departing from the principles of the invention. For example, the photovoltaic device could be based on other semiconductor material such as gallium arsenide and aluminum gallium arsenide. Other materials may also be used to optimize the peak responsivity energy. Also, where other peak responsivity wavelengths may be used, the fiber may be doped with impurities other than chromium and neodymium to optimize the transfer of solar energy to the peak responsivity energy of the photovoltaic device. Further, quantum well photovoltaic devices might be used to enhance its spectral response and efficiency characteristics. See K. Branham, I. Ballard, J. Connolly, N. Ekins-Daukes, B. Kluftinger, J. Nelson and C. Rohr, “Quantum well solar cells,” Physica E. 14 (2002) 27-36; J. Rimada and L. Hernandez, “Modeling of ideal AlGaAs quantum well solar cells,” Microelectronics Journal 32 (2001) 719-723; N. Ahenasy, M. Leibovitch, Y. Rosenwaks, and Y. Shapira, “GaAs/AlGaAs single quantum well p-i-n structures: A surface photovoltage study,” J. Appl. Phys. Vol. 86, No 12, 15 Dec. 1999; and M. Paxman, J. Nelson, B. Braun, J. Connolly, and K. Barnham, “Modeling the spectral response of the quantum well solar cell,” J. Appl. Phys. Vol 74 (1), 1 Jul. 1993, copies of all of which accompany this disclosure and are hereby incorporated by reference in their entirety.

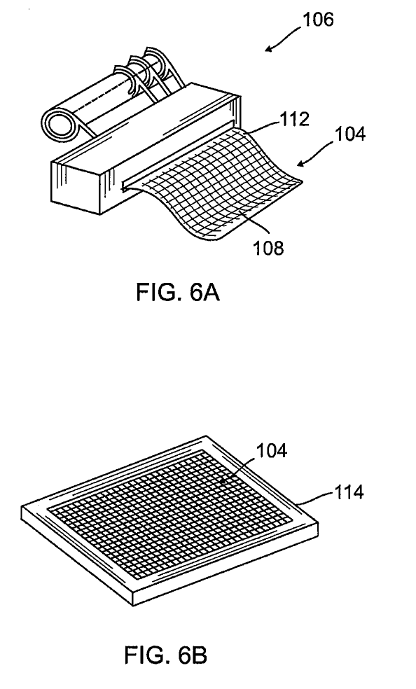

A salient advantage of the solar pumped fiber laser power converter is that many fiber lasers may be woven into a solar fabric 104 by a loom 106 as shown in FIG. 6A. Thus, a first plurality of fiber lasers 108, extending a first direction, is interwoven with a second plurality of fiber lasers 112, extending a second direction the output ends of the fibers illuminating photovoltaic cells as described with respect to FIG. 5A-5C above. Such solar fabrics can then be held by a frame 114 shown in FIG. 6B, or hung from or placed over other structures.

Another embodiment of a solar-to-electrical power conversion device is shown in FIG. 7, where fiber lasers are employed but they are end pumped instead of side pumped. In this case, a plurality of optical fibers 116, each having a conventional core 118 and cladding 120, arranged in parallel in a closely packed array 122. The cores are doped as described above with respect to FIG. 2. A lens 124 is formed on one end 126 of each fiber so as to couple solar radiation into the core 118, and the lens is coated with an antireflective coating 128. Near that end the fiber is also provided with Bragg grating mirror 130 that is essentially 100% reflective at a narrow band of wavelengths corresponding to the relatively narrow band of laser output energy. The other end of each fiber is directly coupled to a photovoltaic device having a thin film coating 132 that is partially reflecting at the laser band, and essentially 100% reflective at essentially all other wavelengths. The thin film coating is followed, for example, by a n-doped layer 134 and an p-doped layer 136, which form a p-n junction 138, each layer having respective electrodes 140 and 142 connected thereto. The n-doped layer is followed by a 100% reflective minor 144. For each fiber, a resonant cavity is formed between the Bragg minor 130 and the partially reflecting coating 132. Thus, solar energy at wavelengths other than in the laser wavelength band is allowed to enter the fiber cores and pump the laser, and what is not absorbed in a first pass through the fiber will be reflected back through the fiber by the coating 132 to be further absorbed. Similarly, laser light that is not absorbed in a first pass through the p-n junction will essentially be reflected back and forth by the mirrors 130, 132 and 144 until fully absorbed.

A further, similar, solar power conversion tile embodiment 146 is shown in FIG. 8, where the fibers are replaced with a monolithic glass layer 148 doped like the fiber of FIG. 1. In this embodiment the surface 150 of the glass layer at the top of the tile is coated with a thin film stack 152 like that which coats the fiber 10 in FIG. 2. The bottom surface 154 of the glass layer has a thin film stack coating like coating 132 of the embodiment of FIG. 7, and the rest of the structure is like that of FIG. 7.

A further solar tile embodiment, shown in FIG. 9, is provided to increase the likelihood that all solar power is absorbed. In this case, several solar power conversion tiles 156 are stacked, the bottom of those tiles 158 being the only one with a 100% reflective mirror, so that solar power not absorbed by the other tiles on a first pass is reflected back through them to be further absorbed. The tiles 156 are like the tiles 146, except for two things. First, instead of a thin film coating that is partially reflective at the laser band and essentially 100% reflective at essentially all other wavelengths, a thin film layer 160 is provided that is partially reflective at the laser band and essentially 100% transmissive at essentially all other wavelengths. Second, it does not include a reflective element at the bottom, so that both solar power not absorbed by the glass and laser power not absorbed by the p-n junction will pass on to the next tile, where the solar radiation will pump the next glass sheet and the laser radiation will be reflected back to the preceding tile. Finally, the tile 158 is like solar tile 146.

The terms and expressions which have been employed in the forgoing specification are used therein as terms of description and not limitation, and there is no intention in the use of such terms and expressions, of excluding equivalents of the features shown and described or portions thereof, it being recognized that the scope of the invention is defined and limited only by such claims as are made based on this disclosure.

What is claimed is:

1. A solar-to-electrical power conversion device, comprising:
a medium that absorbs solar power over a relatively broad range of energies and emits at least a portion of said power as radiation having a relatively narrow range of energies; and
an electromagnetic radiation-to-electrical power conversion device for absorbing said radiation having a relatively narrow range of energies and producing electrical power in response thereto.

2. A method for converting solar power to electrical power, comprising:
providing a medium that absorbs solar power over a relatively broad range of energies and emits at least a portion of said power as radiation having a relatively narrow range of energies;
providing an electromagnetic radiation-to-electrical power conversion device for absorbing said radiation having a relatively narrow range of energies so as to produce electrical power in response thereto; and
illuminating said medium with sunlight.
